(19) United States
(12) Patent Application Publication
(10) Pub. No.: US 2008/0142897 A1
(43) Pub. Date: Jun. 19, 2008

(54) INTEGRATED CIRCUIT SYSTEM HAVING STRAINED TRANSISTOR

(75) Inventors: Young Way Teh, Singapore (SG); Xiangdong Chen, Poughquag, NY (US); Jamin F. Fen, Wappingers Falls, NY (US); Jun Jung Kim, Fishkill, NY (US); Daewon Yang, Hopewell Junction, NY (US); Roman Knoefler, Dresden (DE); Michael P. Belyansky, Bethel, CT (US)

Correspondence Address: LAW OFFICES OF MIKIO ISHIMARU, 333 W. EL CAMINO REAL, SUITE 330, SUNNYVALE, CA, 94087, US

(73) Assignees: CHARTERED SEMICONDUCTOR MANUFACTURING LTD., Singapore (SG); INTERNATIONAL BUSINESS MACHINES CORPORATION, Armonk, NY (US); SAMSUNG, Gyeonggi-do (KR); INFINEON TECHNOLOGIES NORTH AMERICA CORP., San Jose, CA (US)

(21) Appl. No.: 11/613,149

(22) Filed: Dec. 19, 2006

(51) Int. Cl. H01L 27/092

(52) U.S. Cl. 257/369; 257/E27.062

(57) ABSTRACT

An integrated circuit system is provided including forming a circuit element on a wafer, forming a stress formation layer having a non-uniform profile over the wafer, and forming an interlayer dielectric over the stress formation layer and the wafer.

### TECHNICAL FIELD

The present invention relates to the field of integrated circuits and more specifically to integrated circuit with strained transistor.

### BACKGROUND ART

Modern electronics, such as smart phones, personal digital assistants, location based services devices, digital cameras, music players, servers, and storage arrays, are packing more integrated circuits into an ever shrinking physical space with expectations for decreasing cost. Both higher performance and lower power are also quintessential requirements for electronics to continue proliferation into everyday. For example, more functions are packed into a cellular phone with higher performance and longer battery life. Numerous technologies have been developed to meet these requirements.

Integrated circuits are often manufactured in and on silicon and other integrated circuit wafers. Integrated circuits include literally millions of metal oxide semiconductor field effect transistors (MOSFET). Advances in integrated circuit technology continue to shrink the sizes of these transistors and drive for higher performance with minimum power consumption. This dichotomy has inspired various approaches to solve the need for speed at lower power.

One approach involves continued shrinkage of key features of the integrated circuit technology. This approach provides a size reduction but continues to struggle balancing cost, performance, and power. Another approach involves different integrated circuit materials or material systems, such as silicon on insulator (SOI), silicon germanium (SiGe) material, etc. These alternatives provide some performance improvements but are not mainstream today resulting in higher cost as well as constrain volume capacity.

Yet another approach is to provide performance improvement and power reduction while controlling cost. This approach squeezes as much performance, power, or both out of a given integrated circuit technology and manufacturing through a technique called “strained” transistors. This allows use of existing integrated circuit manufacturing and technology investments to keep the cost down or extend future technology generations.

There are various strained integrated circuit approaches. Some approaches use different material systems as the SOI mentioned earlier. Again, these different material systems provide performance improvements but add cost and are not available in volume to satisfy the high volume modern electronics needs. Other “strained” approaches use mainstream integrated circuit technology and manufacturing, such as complementary metal oxide semiconductor (CMOS).

Areas where the paradox of performance, power, and cost are most evident in the modern Ultra-Large Scale Integration era include microprocessors and memories. Both microprocessors and memories in one form or another permeate modern electronics. Microprocessor and memory applications need faster transistor speeds and high drive currents. Integrated circuit technologies used for microprocessors and memories have seen many transistor designs and processing schemes to improve the mobility of carriers to improve performance and lower power consumption. One way to achieve faster switching of a MOS transistor is to design the device with “strained” transistors so that the mobility and velocity of its charge carriers in the channel region are increased.

An appropriate type of stress in the channel region of an n-channel metal oxide semiconductor (NMOS) transistor is known to improve carrier mobility and velocity, which results in increased drive current for the transistor. High tensile material such as silicon nitride supplies a tensile stress in the NMOS region beneath the tensile layer. In order to maintain the performance of PMOS devices, a germanium (Ge) implant process is used to relax the material covering the PMOS device. A resist layer covering the NMOS devices blocks this implant and maintains the tensile stress in the NMOS channel. These techniques are essential in the efforts to develop faster products.

To achieve performance improvement and power reduction in a CMOS device, both the PMOS transistor and the NMOS transistor need to be strained. The PMOS transistor must be strained to provide compression stress to the p-channel while the NMOS transistor must be strained to provide tensile stress to the n-channel. Typically, dual stress liners (DSL) or dual stress contact etch stop liner may be used to accommodate the different stress requirements. The DSL technique has complicated process and integration issues, such as silicide loss and poor contact at the DSL overlap region.

The “strained” transistor approach has other limitations. As integrated circuit technologies evolve, feature sizes continue to shrink. Increased thickness of the stress layer improves transistor performance but constrains the certain feature reductions.

Thus, a need still remains for improving the yield, cost, and size of the basic transistor structures and manufacturing to obtain maximum performance improvement, power reduction, or both. In view of the demand for faster microprocessors and memory devices, it is increasingly critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including forming a circuit element on a wafer, forming a stress formation layer having a non-uniform profile over the wafer, and forming an interlayer dielectric over the stress formation layer and the wafer.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit system in an embodiment of the present invention;

FIG. 2 is a cross-sectional view of the integrated circuit system in a high density plasma phase of the stress formation layer;

FIG. 3 is a cross-sectional view of the structure of FIG. 2 in a protective application phase; and

FIG. 4 is a flow chart of a system for an integrated circuit system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. In addition, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

The term “processing” as used herein includes deposition of material, patterning, exposure, development, etching, cleaning, molding, and/or removal of the material or as required in forming a described structure.

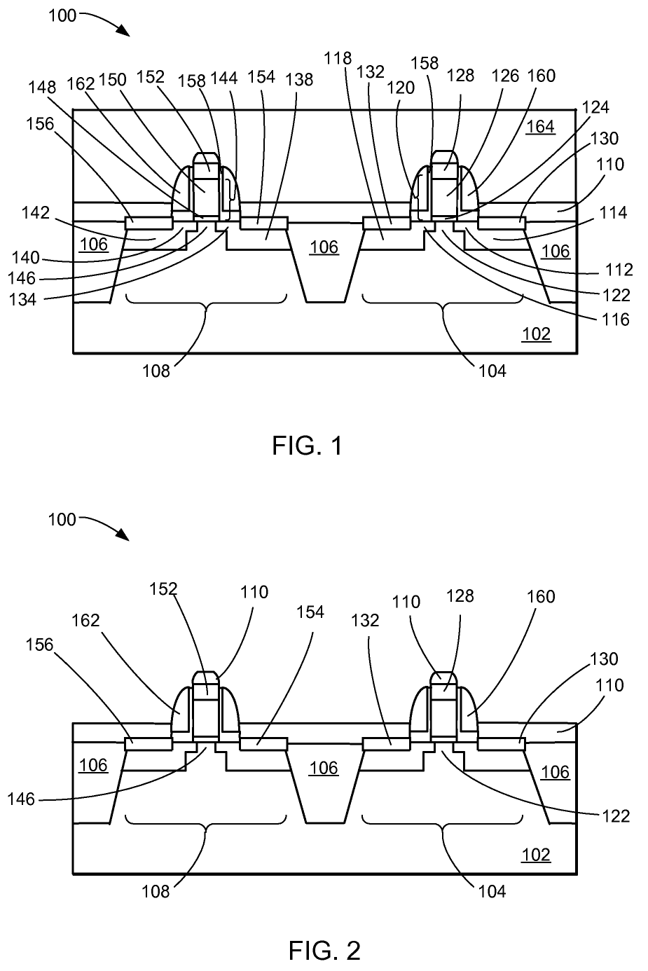

Referring now to FIG. 1, therein is shown a cross-sectional view of an integrated circuit system 100 in an embodiment of the present invention. The integrated circuit system 100 includes a wafer 102, such as a n-type substrate wafer, having a first circuit element 104, isolation regions 106, a second circuit element 108, and a stress formation layer 110, such as a compression layer of nitride or calcium nitride.

The first circuit element 104 and the second circuit element 108 are shown as the same type, such a p-type transistor or a p-type metal oxide semiconductor (PMOS) transistor. The non-uniform configuration and the thickness of the stress formation layer 110 over the first circuit element 104 provides the compression stress for performance improvement of the first circuit element 104 without constraining the feature sizes of the integrated circuit technology process of the integrated circuit system 100. For example, the distance between the first circuit element 104 and the second circuit element 108 are not constrained by the thickness of the stress formation layer 110. This will be described in more detail later.

For illustrative purposes, the first circuit element 104 and the second circuit element 108 are described as the same type, although it is understood that the first circuit element 104 and the second circuit element 108 may be different types, such as a p-type transistor or n-type transistor. Also for illustrative purposes, the isolation regions 106 are shown between the first circuit element 104 and the second circuit element 108, although it is understood that the isolation regions 106 may be optional. For example, the first circuit element 104 and the second circuit element 108 as the same circuit type may not require the isolation regions 106.

The first circuit element 104 includes a first source 112 in the wafer 102. The first source 112, such as a p-type source, includes a first source region 114 implanted into the wafer 102. A first drain 116 is in the wafer 102, wherein the first drain 116 includes a first drain region 118 implanted into the wafer 102. For illustrative purposes, the first circuit element 104 is shown as a transistor, although it is understood that the first circuit element 104 may be any passive circuit element, active circuit element, or any structures, such as routing lines on the wafer 102.

A first gate stack 120 is on the surface of the wafer 102 and over a first channel region 122. The first channel region 122 is part of the wafer 102 and between the first source 112 and the first drain 116. The first gate stack 120 includes a first gate oxide 124, such as a thin gate oxide with high-K dielectric, and a first gate electrode 126.

An oxide liner 158 is adjacent to the first gate stack 120 over the first source 112 and the first drain 116. A first spacer 160 is on the oxide liner 158 surrounding the first gate stack 120 as well as over the first source 112 and the first drain 116.

A silicide layer is over the first gate stack 120, the first source region 114 and the first drain region 118. A first gate contact 128, a first source contact 130 and a first drain contact 132 may be formed from the silicide layer. The first spacer 160 is used to block the deposition of the silicide layer adjacent to the first gate stack 120 to electrically isolate the first source contact 130 and the first drain contact 132 from the first gate stack 120. The first source contact 130 connects with the first source region 114. The first drain contact 132 connects with the first drain region 11 8.

The stress formation layer 110 is a non-uniform layer over the first circuit element 104. The stress formation layer 110 is over the first gate contact 128, the first source contact 130, and the first drain contact 132 with minimum amount or substantially none on the side wall of the first spacer 160. The stress formation layer 110 has sufficient thickness, such as 500 angstrom, providing high compression strain to the first circuit element 104 without requiring additional space that would be required by the substantially same thickness of the stress formation layer 110 if present on the side wall of the first spacer 160.

For illustrative purposes, the stress formation layer 110 is described as a compression stress layer for the first circuit element 104 as a p-type transistor, although it is understood that the stress formation layer 110 may perform different functions, such as tensile stress for the first circuit element 104 as an n-type transistor.

The stress formation layer 110 over the first circuit element 104 provides compression to the first channel region 122. This compression stress strains the first channel region 122 to increase charge, such as holes, mobility thereby increasing performance, lowering power consumption, or both.

Similarly, the second circuit element 108, such as a p-type metal oxide semiconductor (PMOS) transistor, includes a second source 134 in the wafer 102. The second source 134 includes a second source region 138 implanted into the wafer 102. A second drain 140 is formed in the wafer 102 includes a second drain region 142 implanted into the wafer 102.

A second gate stack 144 is on the wafer 102 and over a second channel region 146. The second channel region 146 is part of the wafer 102 located between the second source 134 and the second drain 140. The second gate stack 144 includes a second gate oxide 148 and a second gate electrode 150.

The oxide liner 158 is adjacent to the second gate stack 144 over the second source 134 and the second drain 140. A second spacer 162 is on the oxide liner 158 surrounding the second gate stack 144 as well as over the second source 134 and the second drain 140.

A second gate contact 152, a second source contact 154 and a second drain contact 156 are over the second gate stack 144, the second source region 138 and the second drain region 142, respectively. The second gate contact 152 is on the second gate electrode 150. The second source contact 154 connects with the second source region 138. The second drain contact 156 connects with the second drain region 142.

The stress formation layer 110 is also a non-uniform layer over the second circuit element 108. The stress formation layer 110 is over the second gate contact 152, the second source contact 154, and the second drain contact 156 with minimum amount or substantially none on the side wall of the second spacer 162. The stress formation layer 110 has sufficient thickness, such as 500 angstrom, providing high compression strain to the second circuit element 108 without requiring additional space that would be required by the substantially same thickness of the stress formation layer 110 if present on the side wall of the second spacer 162. An interlayer dielectric 164 is over the stress formation layer 110 protecting the first circuit element 104 and the rest an active side of the wafer 102 for further processing.

Referring now to FIG. 2, therein is shown a cross-sectional view of the integrated circuit system 100 in a high density plasma phase of the stress formation layer 110. High density plasma process forms the stress formation layer 110 over the active side of the wafer 102.

The stress formation layer 110 is formed over the first gate contact 128, the first source contact 130, and the first drain contact 132 with minimal amount or none over the first spacer 160. The stress formation layer 110 is also formed over the second gate contact 152, the second source contact 154, and the second drain contact 156 with minimal amount or none over the second spacer 162.

The first circuit element 104 and the second circuit element 108 as PMOS transistors benefit from the compression stress from the stress formation layer 110, such as a nitride or calcium nitride layer, to improve hole mobility in the first channel region 122 and the second channel region 146, respectively. The high density plasma process forms the thickness, such as 500 angstroms, of the stress formation layer 110 to provide the high compression stress for the first circuit element 104 and the second circuit element 108. An increased thickness of the stress formation layer 110 provides increase compression stress thereby improving the performance of the first circuit element 104 and the second circuit element 108.

As the same type of circuit elements, the isolation regions 106 are optional. For example, as the integrated circuit technology feature size decreases or circuit element density increases, the isolation regions 106 may not be formed between the circuit elements, such as the first circuit element 104 and the second circuit element 108. The minimal amount or none of the stress formation layer 110 on the side wall of the spacers, such as the first spacer 160 and the second spacer 162, allows the first circuit element 104 and the second circuit element 108 closer to each other.

It has been discovered that the high density plasma nitridation to form the stress formation layer 110 over circuit elements increases the circuit element density and enables feature size reduction, such as poly conductive line of the gate stack, of the integrated circuit technology used to manufacture the integrated circuit system 100. The high density plasma nitridation forms the stress formation layer 110 on the spacers with minimum amount or none while forming sufficient thickness over the gate, source, and drain. The sufficient thickness of the stress formation layer 110 provides the high compression stress to improve performance of the first circuit element 104 and the second circuit element 108.

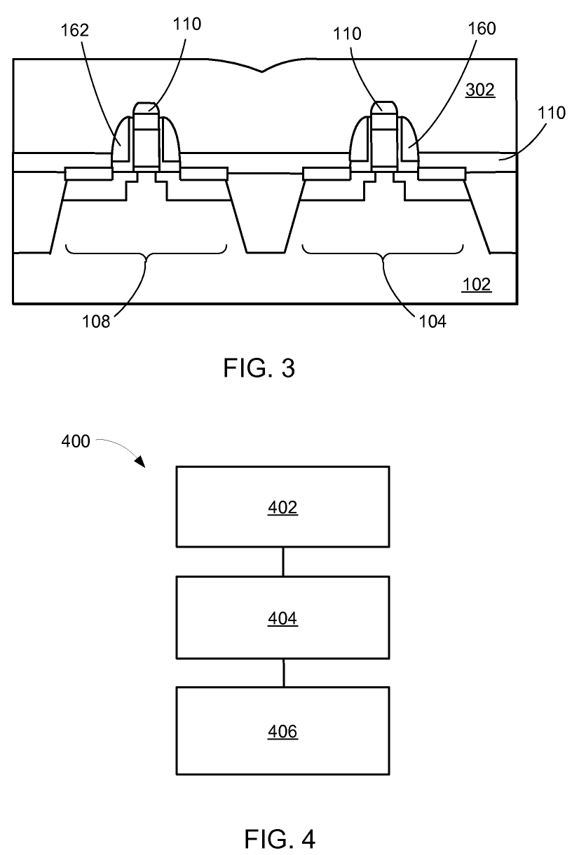

Referring now to FIG. 3, therein is shown a cross-sectional view of the structure of FIG. 2 in a protective application phase. A first interlayer dielectric 302, such as a silicon dioxide layer (SiO₂), is formed on the active side of the wafer 102. The first interlayer dielectric 302 is over the first circuit element 104 and the second circuit element 108. The stress formation layer 110 is also covered by the first interlayer dielectric 302. The first interlayer dielectric 302 undergoes planarization, such as chemical mechanical planarization (CMP), to flatten all the topography. The planarization forms the integrated circuit system 100 ready for further processing.

It has been discovered that the non-uniform profile of the stress formation layer 110, having minimum amount or not on the first spacer 160 and the second spacer 162, helps prevent key holes or voids in the first interlayer dielectric 302.

Referring now to FIG. 4, therein is shown a flow chart of an integrated circuit system 400 for manufacture of the integrated circuit system 100 in an embodiment of the present invention. The system 400 includes forming a circuit element on a wafer in a block 402; forming a stress formation layer having a non-uniform profile over the wafer in a block 404; and forming an interlayer dielectric over the stress formation layer and the wafer in a block 406.

It has been discovered that the present invention thus has numerous aspects.

It has been discovered that the non-uniform profile of the stress formation layer 110 provides flexibility to control the thickness of the stress formation layer 110 as well as increase circuit density or reduce feature size of the integrated circuit technology used to manufacture the integrated circuit system 100.

An aspect of the present invention is that the non-uniform profile of the stress formation layer 110 has minimum amount or no amount on the side walls of the circuit elements. This allows for the circuit elements to be closer to each other. This also allows for feature size reduction of the integrated circuit technology, such as reduce the space between the poly conductive lines.

Another aspect of the present invention is that the non-uniform profile of the stress formation layer 110 provides for flexibility to vary the thickness of the stress formation layer 110. For PMOS transistors, a thicker the compression stress layer further improves the performance of the PMOS transistors.

Yet another important aspect of the present invention is that the non-uniform profile of the stress formation layer 110 helps prevent voids in subsequent interlayer dielectric fills.

Yet another important aspect of the present invention is that the non-uniform profile ob the stress formation layer 110 may be applied with tensile stress material. The tensile stress material for the stress formation layer 110 may be applied to NMOS transistors for performance improvements. The non-uniform profile for NMOS transistors would also benefit feature size reduction as well.

Yet another important aspect of the present invention is that the different stress formation layers may be applied to different portions of the wafer, such as tensile stress layer for NMOS transistors and compression stress layer for PMOS transistors. The non-uniform profile of the different stress formation layers improves the respective transistor performance while reducing feature size of the integrated circuit technology.

Yet another important advantage of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system method and apparatus of the present invention furnish important and heretofore unknown and unavailable solutions, capabilities, and functional aspects for integrated circuit systems. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit system comprising:
forming a circuit element on a wafer;
forming a stress formation layer having a non-uniform profile over the wafer; and
forming an interlayer dielectric over the stress formation layer and the wafer.

2. The system as claimed in claim 1 wherein:
forming the circuit element on the wafer includes:
forming a gate stack of the circuit element; and
forming the stress formation layer having the non-uniform profile further includes:
forming the stress formation layer, having the non-uniform profile, with a mimimal amount thereof along a vertical side of the gate stack.

3. The system as claimed in claim 1 wherein:
forming the circuit element on the wafer includes:
forming a gate stack of the circuit element, and
forming a spacer along a vertical side of the gate stack; and
forming the stress formation layer having the non-uniform profile further includes:
forming the stress formation layer, having the non-uniform profile, with a mimimal amount thereof over the spacer.

4. The system as claimed in claim 1 wherein forming the interlayer dielectric includes forming the interlayer dielectric substantially without voids.

5. The system as claimed in claim 1 wherein forming the stress formation layer includes forming a layer comprised of a compression stressed material.

6. An integrated circuit system comprising:
forming a first transistor and a second transistor on a wafer;
high density plasma depositing a stress formation layer, having a non-uniform profile, comprised of nitride over the first transistor, the second transistor, and the wafer;
forming an interdielectric oxide layer over the stress formation layer, the first transistor, the second transistor, and the wafer.

7. The system as claimed in claim 6 wherein forming the first transistor and the second transistor includes forming p-type transistors.

8. The system as claimed in claim 6 wherein:
forming the first transistor and the second transistor on the wafer includes:
forming a first gate stack of the first transistor,
forming a second gate stack of the second transistor; and
high density plasma depositing the stress formation layer, having the non-uniform profile, further includes:
forming the stress formation layer, having the non-uniform profile, with a mimimal amount thereof along a vertical side of the first gate stack and the second gate stack for space reduction between the first transistor and the second transistor.

9. The system as claimed in claim 6 wherein:
forming the first transistor and the second transistor includes:
forming a first gate stack, a first source region, and a first drain region of the first transistor,
forming a second gate stack, a second source region, and a second drain region of the second transistor; and
high density plasma depositing the stress formation layer, having the non-uniform profile, further includes:
forming the stress formation layer, having the non-uniform profile, over the first gate stack, the first source region, the first drain region, the second gate stack, the second source region, and the second drain region.

10. The system as claimed in claim 6 wherein forming the first transistor and the second transistor includes forming complementary metal oxide semiconductor transistors.

11. An integrated circuit system comprising:
a circuit element on a wafer;
a stress formation layer having a non-uniform profile over the wafer; and
an interlayer dielectric over the stress formation layer and the wafer.

12. The system as claimed in claim 11 wherein:
the circuit element has a gate stack on the wafer; and
the stress formation layer, having the non-uniform profile, has mimimal amount along a vertical side of the gate stack over the wafer.

13. The system as claimed in claim 11 wherein:
the circuit element on the wafer includes:
a gate stack of the circuit element, and
a spacer along a vertical side of the gate stack; and
the stress formation layer having the non-uniform profile further includes:
the stress formation layer, having the non-uniform profile, with a mimimal amount thereof over the spacer.

14. The system as claimed in claim 11 wherein the interlayer dielectric is substantially without voids.

15. The system as claimed in claim 11 wherein the stress formation layer is comprised of a compression stressed material.

16. The system as claimed in claim 11 wherein:
the circuit element includes a first transistor and a second transistor on the wafer;
the stress formation layer, having the non-uniform profile, is comprised of nitride over the first transistor, the second transistor, and the wafer; and
an interlayer dielectric is an interdielectric oxide layer over the stress formation layer, the first transistor, the second transistor, and the wafer.

17. The system as claimed in claim 16 wherein the first transistor and the second transistor are p-type transistors.

18. The system as claimed in claim 16 wherein:
the first transistor and the second transistor on the wafer includes:
a first gate stack of the first transistor,
a second gate stack of the second transistor; and
the stress formation layer, having the non-uniform profile, further includes:
the stress formation layer, having the non-uniform profile, with a mimimal amount thereof along a vertical side of the first gate stack and the second gate stack for space reduction between the first transistor and the second transistor.

19. The system as claimed in claim 16 wherein:
the first transistor and the second transistor includes:
a first gate stack, a first source region, and a first drain region of the first transistor,
a second gate stack, a second source region, and a second drain region of the second transistor; and
the stress formation layer, having the non-uniform profile, is over the first gate stack, the first source region, the first drain region, the second gate stack, the second source region, and the second drain region.

20. The system as claimed in claim 16 wherein the first transistor and the second transistor includes forming complementary metal oxide semiconductor transistors.
